(19) United States
(12) Patent Application Publication
(10) Pub. No.: US 2006/0087228 A1
(43) Pub. Date: Apr. 27, 2006

(54) Substrate for organic electroluminescent element

(75) Inventor: Yoshihiro Kobayashi, Tokyo (JP)

Correspondence Address: SEYFARTH SHAW LLP, 55 E. MONROE STREET, SUITE 4200, CHICAGO, IL, 60603-5803, US

(73) Assignee: Dai Nippon Printing Co., Ltd.

(21) Appl. No.: 11/255,299

(22) Filed: Oct. 21, 2005

(30) Foreign Application Priority Data
Oct. 26, 2004 (JP) 2004-310849

(51) Int. Cl. H05B 33/00

(52) U.S. Cl. 313/504

(57) ABSTRACT

A main object of the present invention is to provide an organic EL element and a substrate for an organic EL element having a good wettability change of the wettability changeable layer by the action of the photocatalyst accompanied by the energy irradiation without the influence of the substrate, the electrode layer and the insulation layer to be the base and the excellent patterning characteristics and light emission characteristics. To attain the above-mentioned object, the present invention provides a substrate for an organic EL element comprising a substrate, an electrode layer formed in a pattern or the substrate, an insulation layer formed between the electrode layer on the substrate, a barrier layer formed on the electrode layer and the insulation layer, and a wettability changeable layer formed on the barrier layer to have the wettability change by the action of a photocatalyst accompanied by the energy irradiation, wherein the barrier layer has the charge injecting property or the charge transporting property, and the function of preventing the disturbance of the wettability change of the wettability changeable layer by the action of the photocatalyst.

### BACKGROUND OF THE INVENTION

1. Field of the Invention

The present invention relates to a substrate for organic electroluminescent element, an organic electroluminescent element using the same, and a production method thereof.

2. Description of the Related Art

In general, as the method of patterning an organic electroluminescent (hereinafter it may be abbreviated as EL) layer, there are a method of a liquid repellent process of the partition wall surface after forming a lyophilic partition wall, and a method of carrying out a lyophilic process of the portion with an organic EL layer forming coating solution applied after forming a liquid repellent partition wall. As the former method, for example as it is disclosed in Japanese Patent Application Laid Open (JP-A) No. 2000-353594, there is a method of carrying out the plasma irradiation with a gas containing a fluorine atom introduced. As the latter method, for example as it is disclosed in JP-A No. 2002-22933, there is a method of providing a protection film to a liquid repellent partition wall and carrying out a lyophilic process with an ultraviolet ray irradiation, an oxygen plasma or the like.

However, the method disclosed in JP-A No. 2000-353594 had a problem that a liquid repellent process using the fluorine gas allowed the gas to adhere to all the organic substance so that selections in materials to form an insulating layer was narrowed.

Furthermore, the method disclosed in JP-A No. 2002-22933 had a problem that productivity thereof was poor because of an additional process of forming a protection film.

In order to solve the problems, for example, JP-A No. 2000-223270 proposes a method of forming a wettability changeable layer containing a photocatalyst so as to have the wettability change by the action of the photocatalyst according to the energy irradiation, and forming a pattern according to the wettability difference on the wettability changeable layer surface by the pattern exposure to the wettability changeable layer for patterning the organic EL layer, utilizing the pattern by the wettability difference. This method is advantageous in that the labor required for he patterning operation can dramatically be reduced.

However, since the wettability changeable layer basically has the insulation property, a problem is involved in that the charge injection efficiency is lowered due to the wettability changeable layer so as to lower the light emission characteristics of the organic EL element.

JP-A No. 2002-15867 therefore discloses a method of including a light emission characteristic improving substance in the wettability changeable layer. According to the method, the light emission characteristic decline of the organic EL element due to the wettability changeable layer can be restrained.

Moreover, also by having a thinner thickness of the wettability changeable layer, the light emission characteristic decline of the organic EL element can be restrained. However, it he thickness of the wettability changeable layer is too thin, it is difficult to form a pattern by the wettability difference. Moreover, due to the influence of the substrate, the electrode layer and the insulation layer to be the base, the wettability change by the photocatalyst function accompanied by the energy irradiation is restrained so that there is a problem of the patterning characteristic decline.

### SUMMARY OF THE INVENTION

In view of the problems, the present invention has been achieved. The main object of the invention is to provide an organic EL element and a substrate for an organic EL element having a good wettability change in the wettability changeable layer by the action of the photocatalyst accompanied by the energy irradiation without the influence of the substrate, the electrode layer and the insulation layer to be the base, and also having the excellent patterning characteristics and light emission characteristics.

To attain the above-mentioned object, the present invention provides a substrate for an organic EL element comprising a substrate, an electrode layer formed in a pattern on the substrate, an insulation layer formed between the electrode layer on the substrate, a barrier layer formed on the electrode layer and the insulation layer, and a wettability changeable layer formed on the barrier layer to have the wettability change by the action of a photocatalyst accompanied by the energy irradiation, wherein the barrier layer has the charge injecting property or the charge transporting property, and the function of preventing the disturbance of the wettability change of the wettability changeable layer by the action of the photocatalyst.

According to the present invention, since a barrier layer is provided between the substrate with the electrode layer and the insulation layer formed and the wettability changeable layer, at the time of changing the wettability of the wettability changeable layer by the action of the photocatalyst accompanied by the energy irradiation, the influence of the substrate, the electrode layer and the insulation layer to be the base to the wettability changeable layer can be restrained. Moreover, since the barrier layer has the function of preventing the disturbance of the wettability change of the wettability changeable layer, the wettability change sensitivity can be improved so that the thickness of the wettability changeable layer can be made thinner while maintaining the patterning characteristics. Therefore, in the case an organic EL element is provided, using the substrate for an organic EL element of the present invention, the charge injection efficiency decline by the wettability changeable layer can be restrained so that good light emission characteristics can be provided.

In the present invention, the wettability changeable layer may be a photocatalyst containing layer which contains a photocatalyst so as to have the wettability change by the action of the photocatalyst accompanied by the energy irradiation. Since the photocatalyst containing layer has the wettability change by the action of the photocatalyst contained in the photocatalyst containing layer itself, it is advantageous in that the pattern can be efficiently formed by the wettability difference with a small number of the production steps.

Moreover, in the present invention, the wettability changeable layer comprises a photocatalyst processing layer containing a photocatalyst and a wettability variable layer to have the wettability change by the action of the photocatalyst accompanied by the energy irradiation. Since such a wettability changeable layer has the layers separately per each function, it is advantageous in that the layer configuration, the combination of the material or the like can be changed easily.

According to the present invention, it is preferable that the wettability changeable layer contains an organopolysiloxane containing a fluoroalkyl group. Since such an organopolysiloxane is contained, the liquid repellent of the portion without the energy irradiation of the wettability changeable layer is improved dramatically, in the case an organic EL element is provided, using a substrate for an organic EL element of the present invention, film formation of the organic EL layer to the liquid repellent region can be prevented. Consequently, the organic EL layer can be formed only in the lyophilic region as the portion with the energy irradiation so as to improve the patterning characteristics.

The present invention also provides the above-mentioned organic EL element comprising the substrate for an organic EL element, an organic EL layer comprising at least a light emitting layer formed on the wettability changeable layer of the substrate for an organic EL element, and a counter electrode layer formed on the organic EL layer. Since the organic EL element of the present invention uses the substrate for an organic EL element mentioned above, it can be produced by a simple method so as to have excellent patterning characteristics and light emission characteristics.

Furthermore, the present invention provides a production method for a substrate for an organic EL element comprising: a barrier layer forming step of forming a barrier layer having the charge injecting property or the charge transporting property, and the function of preventing the disturbance of the wettability change of a wettability changeable layer by the action of a photocatalyst on a substrate with an electrode layer and an insulation layer formed; a wettability changeable layer forming step of forming a wettability changeable layer to have the wettability change by the action of the photocatalyst accompanied by the energy irradiation on the barrier layer; and a wettability changeable pattern forming step of forming a wettability changeable pattern with the wettability of the wettability changeable layer changed by the energy irradiation in a pattern to the wettability changeable layer.

According to the present invention, since a barrier layer is provided between the substrate with the electrode layer and the insulation layer formed and the wettability changeable layer, at the time of changing the wettability of the wettability changeable layer by the energy irradiation in the wettability changeable pattern forming step, the influence of the substrate, the electrode layer and the insulation layer to be the base to the wettability changeable layer can be restrained. Therefore, the wettability changeable pattern can be formed easily with a small energy amount and a short irradiation time. Therefore, the production efficiency of the substrate for an organic EL element can be improved and furthermore, the production cost can be cut back. Moreover, at the time of producing an organic EL element using a substrate for an organic EL element produced by the present invention, since the organic EL layer can be formed easily in a pattern by utilizing the wettability difference of the wettability changeable pattern, a substrate for an organic EL element having the good patterning characteristics can be obtained. Furthermore, as mentioned above, since the barrier layer has the function of preventing the disturbance of the wettability change of the wettability changeable layer, the wettability change process in the wettability changeable pattern forming step can proceed with a high sensitivity. Consequently, the thickness of the wettability changeable layer can be nade thinner while maintaining the patterning characteristics. Therefore, in the case of producing an organic EL element using a substrate for an organic EL element of the present invention, the charge injection efficiency decline by the wettability changeable layer can be restrained so that an organic El element having the good light emission characteristics can be obtained.

Moreover, the present invention provides a production method for an organic electroluminescent element comprising: a substrate for an organic EL element forming step using the production method for the substrate for an organic EL element mentioned above, an organic EL layer forming step of forming an organic EL layer comprising at least a light emitting layer in a pattern on the wettability changeable layer of the substrate for an organic EL element obtained by the above-mentioned substrate for an organic EL element forming step, and a counter electrode forming step of forming a counter electrode on the organic EL layer.

According to the present invention, since the production method for a substrate for an organic EL element mentioned above is used, an organic EL element having the excellent patterning characteristics and light emission characteristics can be produced efficiently with the simple steps.

According to the present invention, by the action of the photocatalyst accompanied by the energy irradiation, the influence of the substrate, the electrode layer and the insulation layer to be the base to the wettability changeable layer can be restrained with the barrier layer. Since the sensitivity of the wettability change is made higher, the wettability can be changed with a small energy amount and a short irradiation time so that the effect of efficiently producing a substrate for an organic EL element having the excellent patterning characteristics can be provided. Moreover, since the sensitivity of he wettability change is high, the thickness of the wettability changeable layer can be made thinner while maintaining the patterning characteristics so as to restrain the decline of the charge injection efficiency by the wettability changeable layer, an organic El element having the good light emission characteristics can be provided.

### BRIEF DESCRIPTION OF THE DRAWINGS

FIG. 1 is a schematic cross-sectional view showing an example of a substrate for an organic EL element of the present invention.

FIG. 2 is a schematic cross-sectional view showing an example of an organic EL element of the present invention.

FIG. 3 is a schematic cross-sectional view showing another example of a substrate for an organic EL element of the present invention.

FIGS. 4A to 4D are an example of the production method for the substrate for an organic EL element of the present invention.

### DESCRIPTION OF THE PREFERRED EMBODIMENT

Hereinafter, a substrate for an organic EL element of the present invention, an organic EL element using the same, and a production method thereof will be explained in detail.

A. Substrate for an Organic EL Element

First, the substrate for an organic EL element of the present invention will be explained.

The substrate for an organic EL element of the present invention comprising a substrate, an electrode layer formed in a pattern on the substrate, an insulation layer formed between the electrode layer on the substrate, a barrier layer formed on the electrode layer and the insulation layer, and a wettability changeable layer formed on the barrier layer to have the wettability change by the action of a photocatalyst accompanied by the energy irradiation, wherein the barrier layer has the charge injecting property or the charge transporting property, and the function of preventing the disturbance of the wettability change of the wettability changeable layer by the action of the photocatalyst.

The substrate for an organic EL element of the present invention will be explained with reference to the drawings.

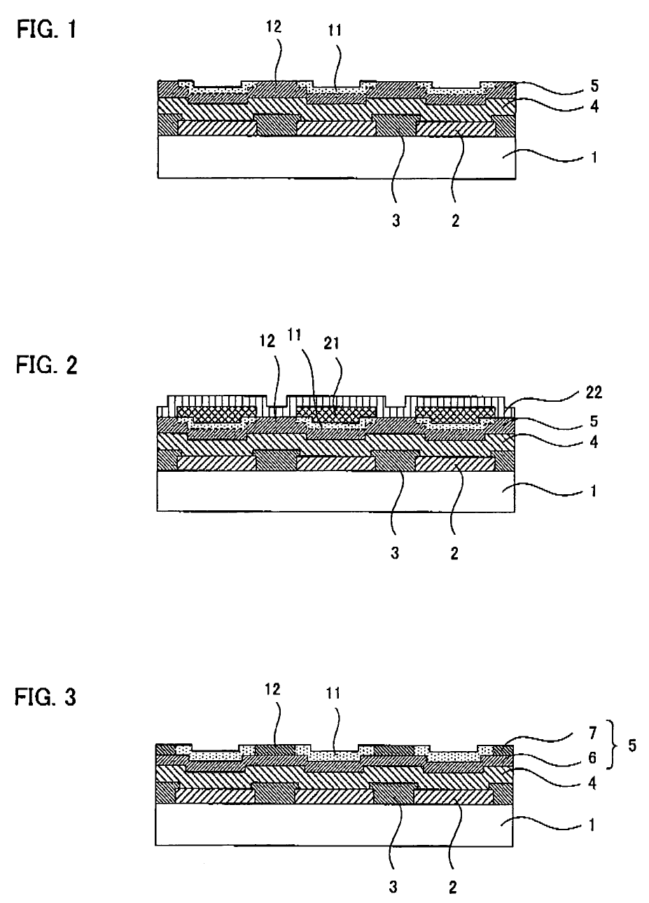

FIG. 1 is a schematic cross-sectional view showing an example of a substrate for an organic EL element of the present invention. In FIG. 1, the substrate for an organic EL element of the present invention comprises an electrode layer 2 and an insulation layer 3 formed on a substrate 1, and a barrier layer 4 and a wettability changeable layer formed on the electrode layer 2 and the insulation layer 3.

Since the wettability changeable layer in the present invention has the wettability change by exciting the photocatalyst with the energy irradiation in a pattern, the portion with the energy irradiation becomes lyophilic and the portion without the energy irradiation becomes liquid repellent. For example as shown in FIG. 1, a wettability changeable pattern comprising a lyophilic region 11 and a liquid repellent region 12 is formed on the surface of the wettability changeable layer 4. According to the present invention, since the barrier layer 4 is formed between the wettability changeable layer 5 and the substrate 1 with the electrode layer 2 and the insulation layer 3 formed, at the time of changing the wettability of the wettability changeable layer 5 by the action of the photocatalyst accompanied by the energy irradiation as mentioned above, the influence of the substrate 1, the electrode layer 2 and the insulation layer 3 to be the base to the wettability changeable layer 5 can be restrained.

Although the action and the function of the barrier layer are not always clear, it is considered that the barrier layer shows the function of preventing diffusion of the impurities or the like from the substrate, the electrode layer or the insulation layer, in particular, the impurities from the insulation layer to be the factor of disturbing the wettability change of the wettability changeable layer with the action of the photocatalyst by forming the barrier layer between the substrate with the electrode layer and the insulation layer formed and the wettability changeable layer. The impurities or the like are considered to influence the action of the photocatalyst, specifically, lower the activity of the photocatalyst. Therefore, by forming the barrier layer, the wettability changing process can be carried out with a high sensitivity. Consequently, the wettability changeable pattern can be obtained with a small energy amount and a short irradiation time.

Moreover, in the case an organic EL element is provided using a substrate for an organic EL element of the present invention, by utilizing the wettability difference in the wettability changeable pattern of the wettability changeable layer, for example as shown in FIG. 2, since the organic EL layer 21 can be formed only on the lyophilic region 11, the patterning operation of the organic EL layer can be facilitated so that a substrate for an organic EL layer having the good patterning characteristics can be provided.

Furthermore, as mentioned above, since the wettability change process can be carried out with a high sensitivity by forming the barrier layer, the thickness of the wettability changeable layer can be made thinner while maintaining the patterning characteristics. Therefore, in the case an organic El element is provided using a substrate for an organic EL element of the present invention, the charge injection efficiency decline by the wettability changeable layer can be restrained so that the light emission characteristics of the organic EL element can be provided preferably.

Hereinafter, each configuration of the substrate for an organic EL element will be explained.

1. Barrier Layer

The barrier layer used in the present invention to be formed on the electrode layer and the insulation layer has the charge injecting property or the charge transporting property as well as the function of preventing the disturbance of the wettability change of the wettability changeable layer by the action of the photocatalyst.

The barrier layer used in the present invention is not particularly limited as long as the barrier layer has the charge injecting property or the charge transporting property as well as the function of preventing the disturbance of the wettability change of the wettability changeable layer by the action of the photocatalyst. According to the present invention, since the electrode layer is formed in a pattern to be, in general, an anode as it will be described later, it is preferable that the barrier layer has the positive hole injecting property or the positive hole transporting property. Specifically, as the material to be used for the barrier layer, a positive hole injecting material capable of stabilizing the injection of the positive hole into the light emitting layer at the time of providing an organic EL element using a substrate for an organic EL element of the present invention, a positive hole transporting material capable of stably transporting the positive hole injected from the anode into the light emitting layer, or the like can be presented.

As the positive hole injecting material or the positive hole transporting material, for example, the polymer based light emitting materials such as a polyparaphenylene vinylene derivative, a polythiophene derivative, a polyparaphenylene derivative, a polysilane derivative, a polyacetylene derivative, a polyvinyl carbazole, a polyfluorene derivative, a polyquinoxaline derivative and a copolymer thereof can be presented. Moreover, for example, a phenyl amine based compound, a star burst type amine based compound, a phthalocyanine based compound, or the oxides such as a vanadium oxide, a molybdenum oxide, a ruthenium oxide, an aluminum oxide and a titanium dioxide, and furthermore, an amorphous carbon, a polyaniline or the like can be used as well.

In the present invention, the wettability changeable layer is formed on the barrier layer. As it will be mentioned in the column of “C. Production method of the substrate for an organic EL element” to be described later, the wettability changeable layer can be formed by coating a wettability changeable layer forming coating solution onto the barrier layer. The wettability changeable layer forming coating solution to be used at the time can be prepared by dissolving or dispersing a photocatalyst or a material to have the wettability change by the action of the photocatalystin a solvent such as water and alcohols. Therefore, It is preferable that the material used for the barrier layer is not dissolved in the solvent such as water and alcohols used for the wettability changeable layer forming coating solution. If the material used for the barrier layer is dissolved by the solvent such as water and alcohols used for the wettability changeable layer forming coating solution the material comprising the barrier layer may partially be eluted at the time of forming the wettability changeable layer so that the wettability changeable layer may hardly be formed.

In the case the positive hole injecting material or the positive hole transporting material is used for the barrier layer accordingly, the barrier layer may also play the role of the positive hole injection layer or the positive hole transporting layer in the organic EL element, or the positive hole injecting and transporting layer comprising a single layer having both the positive hole injecting function and the positive hole transporting function.

Moreover, the barrier layer may either be a single layer or two or more laminated layers.

As for the thickness of the barrier layer used in the present invention, it is not limited as long as the layer has the property and the function mentioned above. Specifically, the thickness can be set preferably within the range of 0.5 nm to 1000 nm, more preferably within the range of 10 nm to 500 nm, and most preferably within the range of 10 nm to 300 nm. In the case the thickness of the barrier layer is too thin, at the time of changing the wettability of the wettability changeable layer, the wettability changeable layer may easily suffer the influence of the substrate, the electrode layer and the insulating layer so that the wettability changeable pattern may hardly be formed. On the other hand, in the case the thickness of the barrier layer is too thick, transportation of the positive hole or the electron can be disturbed so that the adverse effect may be posed to the electric characteristics of the organic EL element at the time of providing an organic EL element using the substrate for an organic EL element of the present invention.

2. Wettability Changeable Layer

The wettability changeable layer used in the present invention is formed on the electrode layer and the insulation layer such that the wettability is changed by the action of the photocatalyst accompanied by the energy irradiation. The wettability changeable layer is not particularly limited as long as the wettability is changed by the action of the photocatalyst accompanied by the energy irradiation. As a preferable embodiment, the case of a wettability changeable layer containing a photocatalyst so as to have the wettability change by the action of the photocatalyst accompanied by the energy irradiation as a photocatalyst containing layer (first embodiment), and the case of a wettability changeable layer comprising a photocatalyst processing layer containing a photocatalyst and a wettability variable layer to have the wettability change by the action of the photocatalyst accompanied by the energy irradiation (second embodiment).

Hereinafter, each embodiment will be explained.

### (1) First Embodiment

The first embodiment of the wettability changeable layer used in the present invention is the photocatalyst containing layer wherein the wettability changes by the action of the photocatalyst accompanied by the energy irradiation. Since the photocatalyst containing layer has the wettability change by the action of the photocatalyst contained in the photocatalyst containing layer itself, it is advantageous in that the wettability changeable pattern can be formed efficiently with a small number of production steps.

The photocatalyst containing layer of this embodiment is not particularly limited as long as it contains a photocatalyst so that the wettability can be changed by the action of the photocatalyst accompanied by the energy irradiation. It is further preferable that it has the function of transporting the electron or the positive hole. Thereby, the electric characteristics of the organic EL element can be improved in the case of providing an organic EL element using the substrate for an organic EL element of the present invention.

Furthermore, the photocatalyst containing layer of the present embodiment contains a material which the wettability thereof changes by the action of the photocatalyst accompanied by the energy irradiation.

The photocatalyst used for the photocatalyst containing layer is not particularly limited as long as it is a substance to generate the electron in the conductive band by the irradiation of a light beam with a wavelength having the energy of the band gap or higher or the radiation so as to generate the positive hole in the valence band. Those known as photo semiconductors, for example a metallic oxide, such as a titanium dioxide (TiO₂), a zinc oxide (ZnO), a tin oxide (SnO₂), a strontium titanate (SrTiO₃), a tungsten oxide (WO₃), a bismuth oxide (Bi₂O₃), and an iron oxide (Fe₂O₃) can be presented. One or two or more kinds as a mixture can be selected and used from them. Among these, in the present embodiment, a titanium dioxide can be used preferably. The titanium dioxide is advantageous that it has high band gap energy, it is chemically stable without the toxicity, and it can be obtained easily.

The titanium dioxides include those of the anatase type and the rutile type belonging to the tetragonal system and those of the brookite type belonging to the ortho rhombic system. In this embodiment, either one can be used, or furthermore, these can be used as a mixture. Among these, in the present embodiment, it is preferable to use the anatase type titanium dioxide. The anatase type titanium dioxide has a 380 nm or less excitation wavelength. As the anatase type titanium dioxide, for example, a hydrochloric acid deflocculation type anatase type titania sol (STS-02 (average particle diameter 7 nm) manufactured by ISHIHARA SANGYO KAISHA, LTD., ST-K01 manufactured by ISHIHARA SANGYO KAISHA, LTD.), or a nitric acid deflocculation type anatase type titania sol (TA-15 (average particle diameter 12 mm) manufactured by Nissan Chemical Industries, Ltd.) can be presented.

Moreover, it is known that the brookite type titanium dioxide has a high photocatalyst activity so that it can be used preferably.

It can be confirmed that the photocatalyst is contained In the photocatalyst containing layer by the X ray photoelectron spectrometry, the Rutherford back scattering spectrometry, nuclear magnetic resonance spectrometry, the mass spectrometry or a combination of thereof.

The content of the photocatalyst in the photocatalyst containing layer is not particularly limited as long as it is an amount of the extent that the wettability of the photocatalyst containing layer can be changed without disturbing the transportation of the positive hole or the electron.

No especial limitation is imposed on the material which changes its wettability by the action of the photocatalyst accompanied by the energy irradiation used in the present embodiment, as long as it is a binder which has a main chain that is not deteriorated or decomposed by action of the photocatalyst. Examples include organopolysiloxanes or the like. Among them, in the present embodiment, it is preferable that the organopolysiloxanes is an organopolysiloxanes containing a fluoroalkyl group.

Examples of such organopolysiloxanes are, for example, (1) an organopolysiloxane which exhibits a large strength and can be obtained by hydrolyzing and polycondensing chloro or alkoxysilane by sol-gel reaction or the like, and (2) an organopolysiloxane obtained by crosslinking a reactive silicone excellent in water repellency or oil repellency.

In the case (1), it is preferably an organopolysiloxane as a hydrolyzed condensation product or a co-hydrolyzed condensation product of one or two or more kinds of silicon compounds represented by the general formula:
YₙSiX₍₄₋ₙ₎

(Here, Y is an alkyl group, a fluoroalkyl group, a vinyl group, an amino group, a phenyl group, or an epoxy group, and X is an alkoxy group, an acetyl group or a halogen. n is an integer from 0 to 3) Here, the number of atoms of the group represented by Y is preferably in a range of 1 to 20. Moreover, the alkoxy group represented by X is preferably a methoxy group, an ethoxy group, a propoxy group, or a butoxy group.

Specifically, a methyl trichloro silane, a methyl tribrom silane, a methyl trimethoxy silane, a methyl triethoxy silane, a methyl triisopropoxy silane, a methyl tri t-butoxy silane; an ethyl trichloro silane, an ethyl tribrom silane, an ethyl trimethoxy silane, an ethyl triethoxy silane, an ethyl triisopropoxy silane, an ethyl tri t-butoxy silane, a n-propyl trichloro silane, a n-propyl tribrom silane, a n-propyl trimetboxy silane, a n-propyl triethoxy silane, a n-propyl triisopropoxy silane, a n-propyl tri t-butoxy silane, a n-hexyl trichloro silane, a n-hexyl tribrom silane, a n-hexyl trimethoxy silane, a n-hexyl triethoxy silane, a n-hexyl triisopropoxy silane, a n-hexyl trit-butoxy silane, a n-decyl trichlorosilane, a n-decyl tribrom silane, a n-decyl trimethoxy silane, a n-decyl triethoxy silane, a n-decyl triisopropoxy silane, a n-decyl tri t-butoxy silane, a n-octadecyl trichloro silane, a n-octadecyl tribrom silane, a n-octadecyl trimethoxy silane, a n-octadecyl triethoxy silane, a n-octadecyl triisopropoxy silane, a n-octadecyl tri t-butoxy silane, a phenyl trichloro silane, a phenyl tribrom silane, a phenyl trimethoxy silane, a phenyl triethoxy silane, a phenyl triisopropoxy silane, a phenyl tri t-butoxy silane, a tetrachloro silane, a tetrabrom silane, a tetramethoxy silane, a tetraethoxy silane, a tetrabutoxy silane, a dimethoxy diethoxy silane, a dimethyl dichloro silane, a dimethyl dibrom silane, a dimethyl dimethoxy silane, a dimethyl diethoxy silane, a diphenyl dichloro silane, a diphenyl dibrom silane, a diphenyl dimethoxy silane, a diphenyl diethoxy silane, a phenyl methyl dichloro silane, a phenyl methyl dibrom silane, a phenyl methyl dimethoxysilane, a phenyl methyl diethoxysilane, a trichloro hydrosilane, a tribrom hydrosilane, a trimethoxy hydrosilane, a triethoxy hydrosilane, a triisopropoxy hydrosilane, a tri t-butoxyhydrosilane, a vinyl trichloro silane, a vinyl tribrom silane, a vinyl trimethoxy silane, a vinyl triethoxy silane, a vinyl triisopropoxy silane, a vinyl tri t-butoxy silane, a trifluoro propyl trichloro silane, a trifluoropropyl tribrom silane, a trifluoropropyl trimethoxy silane, a trifluoro propyl triethoxy silane, a trifluoropropyl triisopropoxy silane, a trifluoro propyl tri t-butoxy silane, a γ-glycidoxy propyl methyl dimethoxysilane, a γ-glycidoxy propyl methyl diethoxy silane, a γ-glycicoxy propyl trimethoxy silane, a γ-glycidoxy propyl triethoxy silane, a γ-glycidoxy propyl triisopropoxy silane, a γ-glycidoxy propyl tri t-butoxy silane, a γ-methacryloxypropyl methyl dimethoxy silane, a γ-methacryloxy propyl methyl diethoxy silane, a γ-methacryloxypropyl trimethoxy silane, a γ-methacryloxy propyl triethoxy silane, a γ-methacryloxy propyl triisopropoxy silane, a γ-methacryloxy propyl tri t-butoxy silane, a γ-amino propyl methyl dimethoxy silane, a γ-amino propyl methyl diethoxy silane, a γ-aminopropyl trimethoxy silane, a γ-amino propyl triethoxy silane, a γ-amino propyl triisopropoxy silane, a γ-amino propyl tri t-butoxy silane, a γ-mercapto propyl methyl dimethoxy silane, a γ-mercapto propyl methyl diethoxy silane, a γ-mercapto propyl trimethoxy silane, a γ-mercapto propyl triethoxy silane, a γ-mercapto propyl triisopropoxy silane, a γ-mercapto propyl tri t-butoxy silane, a β-(3,4-epoxy cyclohexyl) ethyl trimethoxy silane, a β-(3,4-epoxy cyclohexyl) ethyl triethoxy silane, a partial hydrolyzed product thereof, and a mixture thereof can be presented.

Moreover, it is preferable to use an organopolysiloxane having the fluoroalkyl group. Specifically, a hydrolyzed condensation product or a co-hydrolyzed condensation product of one or two or more kinds of the below-mentioned fluoroalkylsilanes can be presented. Those known as a fluorine based silane coupling agent can be used.
CF₃(CF₂)₃CH₂CH₂Si(OCH₃)₃;
CF₃(CF₂)₅CH₂CH₂Si(OCH₃)₃;
CF₃(CF₂)₇CH₂CH₂Si(OCH₃)₃;
CF₃(CF₂)₉CH₂CH₂Si(OCH₃)₃;
(CF₃)₂CF(CF₂)₄CH₂CH₂Si(OCH₃)₃;
(CF₃)₂CF(CF₂)₆CH₂CH₂Si(OCH₃)₃;
(CF₃)₂CF (CF₂)₈CH₂CH₂Si(OCH₃)₃;
CF₃(C₆H₄)C₂H₄Si(OCH₃)₃;
CF₃(CF₂)₃(C₆H₄)C₂H₄Si(OCH₃)₃;
CF₃(CF₂ )₅(C₆H₄)C₂H₄Si(OCH₃)₃;
CF₃(CF₂)₇(C₆H₄)C₂H₄Si(OCH₃)₃;
CF₃(CF₂)₃CH₂CH₂SiCH₃(OCH₃)₂;
CF₃(CF₂)₅CH₂CH₂SiCH₃(OCH₃ )₂;
CF₃(CF₂)₇CH₂CH₂SiCH₃(OCH₃)₂;
CF₃ (CF₂)₉CH₂CH₂SiCH₃ (OCH₃)₂;
(CF₃)₂CF(CF₂)₄CH₂CH₂SiCH₃(OCH₃)₂;
(CF₃)₂CF (CF₂)₆CH₂CH₂SiCH₃(OCH₃)₂;
(CF₃)₂CF (CF₂)₈CH₂CH₂SiCH₃(OCH₃)₂;
CF₃(C₆H₄) C₂H₄SiCH₃(OCH₃)₂;
CF₃(CF2)₃(C₆H₄)C₂H₄SiCH₃(OCH₃)₂;
CF₃(CF₂)₅(C₆H₄)C₂H₄SiCH₃ (OCH₃)₂;
CF₃(CF₂)₇(C₆H₄)C₂H₄SiCH₃ (OCH₃)₂;
CF₃(CF₂)₃CH₂CH₂Si(OCH₂CH₃)₃;
CF₃(CF₂)₅CH₂CH₂Si(OCH₂CH₃)₃;
CF₃(CF₂)₇CH₂CH₂Si(OCH₂CH₃)₃;
CF₃(CF₂)₉CH₂CH₂Si(OCH₂CH₃)₃;
CF₃(CF₂)₇SO₂N(C₂H₅)C₂H₄CH₂Si(OCH₃)₃

By using a polysiloxane containing a fluoroalkyl group as mentioned above as the binder, the liquid repellent of the energy unirradiated portion of the photocatalyst containing layer can dramatically be improved. Therefore, in the case of providing an organic El element using a substrate for an organic EL element of the present invention, the film formation of the organic EL layer to the liquid repellent region of the photocatalyst containing layer can be prevented so that the organic EL layer layer can be formed only in the lyophilic region as the energy irradiated portion.

It can be confirmed that the organopolysiloxane having the fluoroalkyl group is contained in the photocatalyst containing layer by the X ray photoelectron spectrometry, the Rutherford back scattering spectrometry, nuclear magnetic resonance spectrometry, the mass spectrometry or a combination of thereof.

Moreover, as the reactive silicone (2), compounds having a skeleton represented by the following general formula can be presented.

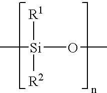

n is an integer of 2 or more, R¹, R² each are a substituted or non substituted alkyl, alkenyl, aryl or cyanoalkyl group having 1 to 10 carbon atoms, and 40% or less of the entirety based on the mole ratio is a vinyl, a phenyl, or a halogenated phenyl. Moreover, those having R¹, R² as a methyl group are preferable since the surface energy becomes the smallest, and it is preferable that a methyl group accounts for 60% or more based on the mole ratio. Moreover, at least one reactive group such as a hydroxyl group is provided in a molecular chain at the chain end or the side chain.

Moreover, together with the above-mentioned organopolysiloxane, a stable organosilicon compound with no cross-linking reaction such as a dimethylpolysiloxane may be mixed to a binder.

In the present embodiment, a surfactant which can be decomposed by action of the photocatalyst and has a function of varying the wettability by the decomposition can be included in the photocatalyst containing layer. Specifically, hydrocarbons of the respective series of NIKKO L BL, BC, BO, and BB manufactured by Nikko Chemicals Co., Ltd., and fluorine base or silicone base nonionic surfactants such as ZONYL FSN and FSO manufacture by Du Pont Kabushiki Kaisha, Surflon S-141 and 145 manufactured by ASAHI GLASS CO., LTD., Megaface F-141 and 144 manufactured by DAINIPPON INK AND CHEMICALS, Inc., FTERGENT F-200 and F251 manufactured by NEOS, UNIDYNE DS-401 and 402 manufactured by DAIKIN INDUSTRIES, Ltd., and Fluorad FC-170 and 176 manufactured by 3M can be cited, and cationic surfactants, anionic surfactants and amphoteric surfactants also can be used.

Other than the surfactants, oligomers and polymers such as polyvinyl alcohol, unsaturated polyester, acrylic resin, polyethylene, diallyl phthalate, ethylene propylene diene monomer, epoxy resin, phenol resin, polyurethane, melamine resin, polycarbonate, polyvinyl chloride, polyamide, polyimide, styrene-butadiene rubber, chloroprene rubber, polypropylene, polybutylene, polystyrene, polyvinyl acetate, polyester, polybutadiene, polybenzimidazole, polyacrylonitrile, epichlorohydrine, polysulfide, polyisoprene and the like can be included in the photocatalyst containing layer.

A thickness of the photocatalyst containing layer in the present embodiment is preferably from 10 nm to 1000 nm, more preferably from 10 nm to 500 nm, and particularly preferably, from 10 nm to 200 nm. If the photocatalyst containing layer is too thin, the wettability difference can not be shown clearly so that the wettability changeable pattern can hardly be formed. On the other hand, in the case the thickness of the photocatalyst containing layer is too thick, transportation of the positive hole or the electron can be disturbed so that the adverse effect may be posed to the electric characteristics of the organic EL element at the time of providing an organic EL element using the substrate for an organic EL element of the present invention.

Moreover, the lyophilic region of the wettability changeable pattern formed on the photocatalyst containing layer surface is not particularly limited as long as it is a region having a contact angle with respect to a liquid smaller than that of the liquid repellent region. Since the specific values of the contact angle with respect to a liquid in the lyophilic region and the liquid repellent region are mentioned in the column of “C. Production method for a substrate for an organic EL element, 3. Wettability changeable pattern forming step” to be described later, explanation is omitted here.

### (2) Second Embodiment

The second embodiment of the wettability changeable layer used in the present invention comprises, for example as shown in FIG. 3, a photocatalyst processing layer 6 containing a photocatalyst and a wettability variable layer 7 to have the wettability change by the action of the photocatalyst accompanied by the energy irradiation. Since the wettability changeable layer having the photocatalyst processing layer and the wettability variable layer have the layers separately for each function, it is advantageous in that the layer configuration, the material combination or the like can be changed easily.

Hereinafter, the photocatalyst processing layer and the wettability variable layer will be explained.

(i) Photocatalyst Processing Layer

The photocatalyst processing layer used in this embodiment is not particularly limited as long as it contains a photocatalyst such that the photocatalyst in the photocatalyst processing layer can change the wettability of the laminated wettability variable layer, and it preferably has the function of transporting the electron or the positive hole. Thereby, in the case an organic EL element is provided using a substrate for an organic EL element of the present invention, the electric characteristics of the organic EL element can be improved.

Moreover, the photocatalyst processing layer may comprise either a photocatalyst alone or a mixture of a photocatalyst and a binder. In the case of the photocatalyst processing layer comprising a photocatalyst and a binder, it is advantageous in that the photocatalyst processing layer can be formed easily. As the binder to be sued for the photocatalyst processing layer, the same binders used for the photocatalyst containing layer of the first embodiment can be used. Since the photocatalyst is the same as those disclosed for the first embodiment, explanation is omitted here.

In the case the photocatalyst processing layer comprises a photocatalyst and a binder, the content of the photocatalyst in the photocatalyst processing layer is not particularly limited as long as it is an amount to the extent capable of changing the wettability of the wettability variable layer without disturbing the transportation of the positive hole or the electron.

Furthermore, the wettability of the photocatalyst processing layer surface may either be lyophilic or liquid repellent.

Moreover, a thickness of the photocatalyst processing layer is preferably from 10 nm to 1000 nm, more preferably from 10 nm to 500 nm, and most preferably from 10 nm to 200 nm. If the photocatalyst processing layer is too thin, it may be difficult to change the wettability of the wettability variable layer. On the other hand, in the case he thickness of the photocatalyst processing layer is too thick, transportation of the positive hole or the electron can be disturbed so that the adverse effect may be posed to the electric characteristics of the organic EL element at the time of providing an organic EL element using the substrate for an organic EL element of the present invention.

(ii) Wettability Variable Layer

The wettability variable layer used in the present embodiment is not particularly limited as long as it contains a material which the wettability thereof changes by the action of the photocatalyst accompanied by the energy irradiation. As for the material which the wettability thereof changes by the action of the photocatalyst accompanied by the energy irradiation, it is the same as the one explained in the first embodiment. Thus, the explanation is omitted here.

In the wettability variable layer, the same surfactant, additives, or the like as the ones described in the first embodiment can be contained.

Furthermore, the wettability variable layer may contain a charge transporting property improving substance for the purpose of improving the charge transporting property for transporting the electron or the positive hole.

A thickness of the wettability variable layer is not particularly limited as long as it is a thickness of the extent that it can form a wettability changeable pattern as well as not disturbing the transportation of the electron or the positive hole.

Since the lyophilic region and the liquid repellent region of the wettability changeable pattern formed on the wettability variable layer surface are the same as the lyophilic region and the liquid repellent region of the wettability changeable pattern formed on the photocatalyst containing layer surface of the first embodiment, explanation is omitted here.

3. Electrode Layer

The electrode layer used in the present invention is formed on the substrate in a pattern. Although the electrode layer used in the present invention may either be an anode or a cathode, in general it is formed as an anode.

Moreover, the electrode layer may either be transparent or not, and it may be selected optionally according to the light taking out surface or the receiving surface or the like. At the time of providing an organic El element using a substrate for an organic EL element of the present invention, for example in the case of taking out the light beam from the electrode layer side, the electrode layer needs to be transparent or semitransparent.

As the anode, it is preferable to use a conductive material having a large work function for facilitating the positive hole injection. Specifically, a metal having a large work function such as an ITO, an indium oxide, and a gold, a conductive polymer such as a polyaniline, a polyacetylene, a polyalkyl thiophene derivative, and a polysilane derivative, or the like can be presented.

Moreover, it is preferable that the electrode layer has a small resistance. In general, a metal material is used, however, an organic compound or an inorganic compound may be used as well.

As for the method of forming such electrode layer, a conventional forming method of the electrode can be employed. For example, PVD method such as vacuum deposition method, sputtering method, or ion plating method, or CVD method can be cited. For a patterning method of the electrode layer, there is no particular limitation imposed as long as a desired pattern can be formed precisely, however, photolithography method or the like can be cited as a specific example.

4. Insulation Layer

The insulation layer used in the present invention is formed between the electrode layers formed in a pattern on the substrate. In general, the insulation layer is formed so as to cover the end parts of the electrode layer.

The insulation layer is provided for stopping the charge supply from the electrode layer to the organic EL layer in the case of providing an organic EL element using a substrate for an organic EL element of the present invention. Moreover, the portion with the insulation layer formed can be a portion without the light emission.

For such an insulation layer, a photo setting resin such as a photosensitive polyimide resin and an acrylic based resin, a thermosetting resin, an inorganic material, or the like can be used.

Moreover, for a forming method of the insulation layer, those methods known in general, such as the photolithography method or the printing method, can be employed.

5. Substrate

The substrate used in the present invention is not particularly limited as long as it supports the electrode layer, the insulation layer, the barrier layer, the wettability changeable layer or the like mentioned above and it has a predetermined strength. In the present invention, in the case the electrode layer has a predetermined strength, the electrode layer may serve also as the substrate, but in general the electrode layer is formed on a substrate having a predetermined strength.

The substrate is not particularly limited as long as the electrode layer, insulation layer or the like can be formed. For example, whether or not the light transmission property is needed is determined optionally according to the light taking out surface or the receiving surface. Since it is in general preferable to have the substrate side as the light taking out surface or the receiving surface, the substrate is preferably made of a transparent material.

As the material for forming such a substrate, for example, a glass plate of a soda lime glass, an alkaline glass, a lead alkaline glass, a borosilicate glass, an alumino silicate glass, a silica glass, or the like, or a resin substrate capable of being shaped as a film or the like can be used. It is preferable that the resin used for the resin substrate is a polymer material having relatively high solvent resistance and heat resistance. Specifically, a fluorine based resin, a polyethylene, a polypropylene, a polyvinyl chloride, a polyvinyl fluoride, a polystyrene, an ABS resin, a polyamide, a polyacetal, a polyester, a polycarbonate, a modified polyphenylene ether, a polysulfon, a polyallylate, a polyether imide, a polyether sulfon, a polyamide imide, a polyimide, a polyphenylene sulfide, a liquid crystalline polyester, a polyethylene terephthalate, a polybutylene terephthalate, a polyethylene naphthalate, a polymicroyxylene dimethylene terephthalate, a polyoxy methylene, a polyether sulfon, a polyether ether ketone, a polyacrylate, an acrylonitrile-styrene resin, a phenol resin, a urea resin, a melamine resin, an unsaturated polyester resin, an epoxy resin, a polyurethane, a silicone resin, an amorphous polyolefin or the like can be presented.

Moreover, in addition to the examples, a polymer material satisfying predetermined conditions can also be used, and a copolymer of two or more kinds may be used as well. Furthermore, as needed, a substrate having the gas barrier property of blocking the gas such as the moisture content and the oxygen can be used.

Moreover, in the present invention, a light shielding part may be provided on the substrate. In the case the light shielding part is formed, by directing an energy from the substrate side, the wettability of the wettability changeable layer surface in the portion without the light shielding part provided can be changed without using a mask or drawing by a laser beam or the like. It is therefore unnecessary to position a mask precisely onto the wettability changeable layer and the step can be simplified. Consequently, it is unnecessary to use any expensive device for drawing irradiation, thereby producing an advantage for costs.

As to the position for forming such a light shielding part, there are the case of forming the light shielding part on the substrate and forming the wettability changeable layer thereon, that is, between the substrate and the wettability changeable layer, and the case of forming as a pattern on the surface on the side without the formation of the wettability changeable layer of the substrate.

The method for forming the light shielding part is not particularly limited, and may be appropriately selected in accordance with the property of the face where the light shielding part is to be formed, power for shielding required energy, and others. For instance, a metal thin film that is made of chromium or the like and formed into a thickness of about 1000 to 2000 Å by a sputtering method, a vacuum deposition method or the like is formed and patterned to form a shielding part. As the patterning method, an ordinary patterning method such as the sputtering can be used.

A method may be one by which a layer that contains light-shielding particles such as carbon particulates, metal oxides, inorganic pigments and organic pigments in a resin binder is formed in a pattern. As the resin binders that can be used, a polyimide resin, acrylic resin, epoxy resin, polyacrylamide, polyvinyl alcohol, gelatin, casein, cellulose and the like can be used singularly or in combination of two or more kinds, and furthermore a photosensitive resin and an O/W emulsion type resin composition such as emulsified reactive silicone can be used. A thickness of such resinous light-shielding part can be set in the range of 0.5 to 10 μm. As a method of patterning such resinous light-shielding part, methods such as a photolithography method and a printing method that are generally used can be used.

For the production method of a substrate for the organic EL element, it will be described in the column of “C. Production method for the substrate for an organic EL element”. Thus, an explanation is omitted here.

B. Organic EL Element

Next, the organic EL element of the present invention will be explained.

The organic EL element of the present invention comprises the substrate for an organic EL element mentioned above, an organic EL layer having at least a light emitting layer, formed on the wettability changeable layer of the substrate for an organic EL element, and a counter electrode layer formed on the organic EL layer.

For example as shown in FIG. 2, the organic EL element of the present invention comprises a substrate 1, an electrode layer 2 and an insulation layer 3 formed on the substrate 1, a barrier layer 4 formed on the electrode layer 2 and the insulation layer 3, a wettability changeable layer 5 formed on the barrier layer 4, an organic EL layer 21 formed on the region with the wettability of the wettability changeable layer 5 changed by the action of the photocatalyst accompanied by the energy irradiation (lyophilic region 11), and a counter electrode layer 22 formed so as to cover the entirety of the organic EL layer 21.

In the present invention, since the above-mentioned substrate for an organic EL element is used, at the time of changing the wettability of the wettability changeable layer, the influence to the wettability changeable layer from the substrate, the electrode layer or the insulation layer to be the base can be restrained by the barrier layer. Thereby, the good patterning characteristics of the organic EL element can be provided so that an organic EL element can be produced by a simple method. Moreover, as mentioned above, since the barrier layer has the function of preventing the disturbance of the wettability change of the wettability changeable layer, the sensitivity of the wettability change can be made higher so that the thickness of the wettability changeable layer can be made thinner while maintaining the patterning characteristics. Therefore, the decline of the charge injection efficiency by the wettability changeable layer can be restrained so that the decline of the light emitting characteristics can be restrained.

Hereinafter, the organic EL layer and the counter electrode layer in the organic EL element of the present invention will be explained.

1. Organic EL Layer

The organic EL layer used in the present invention comprises one layer or a plurality of organic layers including at least a light emitting layer. That is, the organic EL layer is a layer including at least a light emitting layer, with the layer configuration of one organic layer or more. In general, in the case the organic EL layer is formed with the wet process by coating, since the lamination of a large number of layers is difficult according to the relationship with the solvent, it is formed as one layer or two layers of organic layers in many cases. However, it is also possible to provide a larger number of layers by skillfully using the organic material or employing the vacuum deposition method in a combination.

As the organic layers formed in the organic EL layer in addition to the light emitting layer, a charge injection layer such as a positive hole injection layer and an electron injection layer can be presented. Furthermore, as the other organic layers, a charge transporting layer such as a positive hole transporting layer for transporting the positive hole to the light emitting layer, and an electron transporting layer for transporting the electron to the light emitting layer can be presented. In general, these layers can be provided integrally with the charge injection layer by providing the charge transporting function to the charge injection layer. Additionally, as the organic layer formed in the organic EL layer, a layer for preventing piercing of the positive hole or the electron for improving the recombining efficiency such as a carrier block layer can be presented.

In the present invention, as mentioned above, for the barrier layer of the substrate for an organic EL element, in the case the positive hole injecting material or the positive hole transporting material is used, the barrier layer may also play the role of a positive hole injection layer, a positive hole transporting layer, or a positive hole injecting and transporting layer as a single layer having the both functions of the positive hole injecting function and the positive hole transporting function. In this case, as the organic EL layer, the positive hole injection layer, the positive hole transporting layer, or the single positive hole injecting and transporting layer having the positive hole injecting function and the positive hole transporting function need not be provided.

Hereinafter, each configuration of such an organic EL layer will be explained.

(1) Light Emitting Layer

As the light emitting layer as the essential configuration of the organic EL layer in the present invention, for example, a light emitting material such as a pigment based light emitting material, a metal complex based light emitting material, and a polymer based light emitting material can be used.

As the pigment based light emitting material, for example, a cyclopentadiene derivative, a tetraphenyl butadiene derivative, a triphenyl amine derivative, an oxadiazol derivative, a pyrazoloquinoline derivative, a distyryl benzene derivative, a distyryl arylene derivative, a silol derivative, a thiophene ring compound, a pyridine ring compound, a perynon derivative, a perylene derivative, an oligothiophene derivative, a triphmanyl amine derivative, an oxadiazol dimer, a pyrazoline dimer or the like can be presented.

Moreover, as the metal complex based light emitting material, for example, metal complexes having an Al, a Zn, a Be or the like as the central metal, or a rare earth metal such as a Tb, an Eu, a Dy or the like, and an oxadiazol, a thiadiazol, a phenyl pyridine, a phenyl benzoimidazol, a quinoline structure or the like as the ligand, such as an aluminum quinolinol complex, a benzoquinolinol beryllium complex, a benzoxazol zinc complex, a benzothiazol zinc complex, an azomethyl zinc complex, a porphiline zinc complex, an europium complex or the like can be presented.

Furthermore, as the polymer based light emitting material, for example, a polyparaphenylene vinylene derivative, a polythiophene derivative, a polyparaphenylene derivative, a polysilane derivative, a polyacetylene derivative, a polyvinyl carbazol or the like, a polyfluolene derivative, a polyquinoxaline derivative, a polymer thereof or the like can be presented.

For the purpose of improving the light emitting efficiency, changing the light emitting wavelength or the like, an additive such as a doping agent may be added into the light emitting layer. As such a doping agent, for example, a perylene derivative, a coumarin derivative, a rubrene derivative, a quinacridone derivative, a squalium derivative, a porphiline derivative, a styryl based pigment, a tetracene derivative, a pyrazoline derivative, a decacyclene, a phenoxazone, a quinoxaline derivative, a carbazol derivative, and a fluolene derivative can be presented.

The thickness of the light emitting layer is not particularly limited as long as it is a thickness capable of providing the field for recombination of the electron and the positive pole so as to provide the light emitting function. For example it can be about 1 nm to 500 nm.

In the present invention, as mentioned above, in the case the barrier layer also plays the role of the positive hole injection layer, the positive hole transporting layer or the positive hole injecting and transporting layer comprising a single layer having the positive hole injecting function and the positive hole transporting function, it is preferable to form a light emitting layer in a pattern as the organic EL layer on the wettability changeable layer. Since the light emitting layer is formed in a pattern so as to provide the light emitting layers of the three colors of red, green and blue, an organic EL element capable of providing the color display can be obtained.

(2) Charge Injecting and Transporting Layer

In the present invention, the charge injecting and transporting layer may be formed between the electrode layer or the counter electrode layer and the light emitting layer. The charge injecting and transporting layer here has the function of stably transporting the charge from the electrode layer or the counter electrode layer to the light emitting layer. By providing such a charge injecting and transporting layer between the light emitting layer and the electrode layer or the counter electrode layer, the charge injection to the light emitting layer can be stabilized so as to improve the light emitting efficiency.

As such a charge injecting and transporting layer, there are a positive hole injecting and transporting layer for transporting the positive bole injected from the anode into the light emitting layer, and an electron injecting and transporting layer for transporting the electron injected from the cathode into the light emitting layer. Hereinafter, the positive hole injecting and transporting layer and the electron injecting and transporting layer will be explained.

(i) Positive Hole Injection and Transporting Layer

The positive hole injection and transporting layer used in the present invention may be one of the positive hole injection layer for injecting the positive hole into the light emitting layer or the positive hole transporting layer for transporting the positive hole, a lamination of the positive hole injection layer and the positive hole transporting layer, or a single layer having the both functions of the positive hole injecting function and the positive hole transporting function.

In the present invention, since the electrode layer of the substrate for an organic EL element is in general an anode, the positive hole injection and transporting layer is formed between the light emitting layer and the electrode layer.

The material used for the positive hole injection and transporting layer is not particularly limited as long as it is a material capable of stably transporting the positive hole injected from the anode into the light emitting layer. In addition to the compounds presented for the light emitting material, phenyl amine based, star burst type amine based, or phthalocyanine based, oxides such as a vanadium oxide, a molybdenum oxide, a ruthenium oxide, an aluminum oxide, and a titanium dioxide, an amorphous carbon, a polyaniline, a polythiophene, a polyphenylene vinylene derivative or the like can be used. Specifically, a bis(N-(1-naphthyl-N-phenyl) benzidine (α-NPD), a 4,4,4-tris(3-methyl phenyl phenyl amino) triphenyl amine (MTDATA), a poly 3,4 ethylene dioxythiophene-polystyrene sulfonic acid (PEDOT-PSS), a polyvinyl carbazol (PVCz) or the like can be presented.

Moreover, the thickness of the positive hole injection and transporting layer is not particularly limited as long as it is a thickness capable of sufficiently performing the function of injecting the positive hole from the anode and transporting the positive hole to the light emitting layer. Specifically, it is in a range of 0.5 nm to 1,000 nm, in particular it is preferably in a range of 10 nm to 500 nm.

(ii) Electron Injection and Transporting Layer

The electron injection and transporting layer used in the present invention may be one of the electron injection layer for injecting the electron into the light emitting layer or the electron transporting layer for transporting the electrons a lamination of the electron injection layer and the electron transporting layer, or a single layer having the both functions of the electron injecting function and the electron transporting function.

In the present invention, since the counter electrode layer is in general a cathode, the electron injection and transporting layer is formed between the light emitting layer and the counter electrode layer.

The material used for the electron injection layer is not particularly limited as long as it is a material capable of stabilizing the electron injection into the light emitting layer. In addition to the compounds presented for the light emitting material, alkaline metals such as an aluminum lithium alloy, a lithium fluoride, a strontium, a magnesium oxide, a magnesium fluoride, a strontium fluoride, a calcium fluoride, a barium fluoride, an aluminum oxide, a strontium oxide, a calcium, a polymethyl methacrylate, a sodium polystyrene sulfonate, a lithium, a cesium, and a cesium fluoride, halides of the alkaline metals, organic complexes of the alkaline metals or the like can be used.

The thickness of the electrode injection layer is not particularly limited as long as it is a thickness capable of sufficiently performing the electron injection function.

Moreover, the material used for the electron transporting layer is not particularly limited as long as it is a material capable of transporting the electron injected from the electrode layer or the counter electrode layer into the light emitting layer. For example, a bathcuproine, a bathphenanthroline, a phenanthroline derivative, a triazol derivative, an oxadiazol derivative, a tris(8-quilinolato) aluminum complex (Alq₃) or the like can be presented.

The thickness of the electron transporting layer is not particularly limited as long as it is a thickness capable of sufficiently performing the electron transporting function.

Furthermore, as the electron injection and transporting layer comprising a single layer having the both functions of the electron injecting function and the electron transporting function, a metal doping layer with an alkaline metal or an alkaline earth metal doped to an electron transporting organic material may be formed so as to provide the electron injection and transporting layer. As the electron transporting organic material, for example, a bathcuproine, a bathphenanthroline, a phenanthroline derivative or the like can be presented. As the doping metal, a Li, a Cs, a Ba, a Sr or the like can be presented.

The thickness of the electron injection and transporting layer comprising a single layer is not particularly limited as long as it is a thickness capable of sufficiently performing the electron injecting function and the electron transporting function.

2. Counter Electrode Layer

The counter electrode layer used in the present invention is formed on the organic EL layer, facing the electrode layer of the substrate for an organic EL element The counter electrode layer used in the present invention may either be an anode or a cathode, but in general it is formed as a cathode.

Moreover, the counter electrode layer may either be transparent or not, and it may be selected optionally according to the light taking out surface, the light receiving surface or the like. For example, in the case of taking out a light beam from the counter electrode Layer side, the counter electrode layer needs to be transparent or semitransparent.

For the cathode, it is preferable to use a conductive material having a small work function for facilitating the electron injection. For example, magnesium alloys such as MgAg, aluminum alloys such as AlLi, AlCa, and AlMg, alkaline metals and alkaline earth metals such as Li and Ca, alloys of the alkaline metals and the alkaline earth metals or the like can be presented.

Moreover, it is preferable that the counter electrode layer has a small resistance. In general, a metal material is used, but an organic compound or an inorganic compound may be used as well.

As for the other points of the counter electrode layer, they are the same as the ones described in the column of “A. Substrate for an organic EL element 3. Electrode layer” mentioned above. Thus, an explanation is omitted here.

Moreover, for the production method of the organic EL element of the present invention, it is to be explained in the column of “D. Production method for the organic EL element”. Thus, an explanation is omitted here.

C. Production Method for the Substrate for an Organic EL Element

Next, the production method for the substrate for an organic EL element of the present invention will be explained.

A production method for a substrate for an organic EL element of the present invention comprising: a barrier layer forming step of forming a barrier layer having the charge injecting property or the charge transporting property, and the function of preventing the disturbance of the wettability change of a wettability changeable layer by the action of a photocatalyst on a substrate with an electrode layer and an insulation layer formed; a wettability changeable layer forming step of forming a wettability changeable layer to have the wettability change by the action of the photocatalyst accompanied by the energy irradiation on the barrier layer; and a wettability changeable pattern forming step of forming a wettability changeable pattern with the wettability of the wettability changeable layer changed by the energy irradiation in a pattern to the wettability changeable layer.

The production method for the substrate for an organic EL element of the present invention will be explained with reference to the drawings.

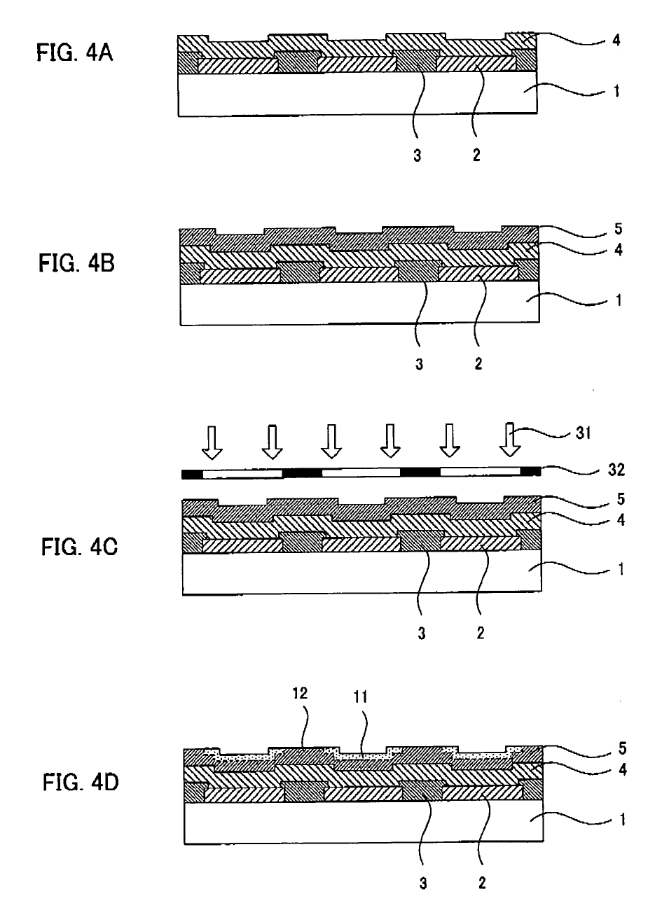

FIGS. 4A to 4D show an example of the production method for the substrate for an organic EL element of the present invention. According to the production method for the substrate for an organic EL element of the present invention, first, a substrate 1 with an electrode layer 2 and an insulation layer 3 formed is prepared by forming the electrode layer 2 in a pattern on the substrate 1 and forming the insulation layer 3 between the electrode layer 2 so as to cover the end part of the electrode layer 2 (FIG. 4A, barrier layer forming step). Next, a wettability changeable layer 5 is formed on the entire surface on the barrier layer 4 (FIG. 4B, wettability changeable layer forming step). Then, a wettability changeable pattern comprising a lyophilic region 11 and a liquid repellent region 12 is formed by directing an energy 31 onto the wettability changeable layer 5 via a photo mask 32 in a pattern for changing the wettability of the wettability changeable layer 5 surface (FIGS. 4C and 4D, wettability changeable pattern forming step). Accordingly, the substrate for an organic EL element can be produced.

In the present invention, the wettability of the wettability changeable layer 5 surface is changed by exciting the photocatalyst with the energy 31 irradiation in a pattern to the wettability changeable layer 5. According to the present invention, since the barrier layer 4 is provided between the wettability changeable layer 5 and the substrate 1 with the electrode layer 2 and the insulation layer 3 formed, at the time of changing the wettability of the wettability changeable layer 5 by irradiating the energy 31 in the wettability changeable pattern forming step (FIG. 4C), the influence to the wettability changeable layer 5 can be restrained. Therefore, with the small energy amount and the short irradiation time, the wettability changeable pattern comprising the lyophilic region 11 and the liquid repellent region 12 can easily be formed (FIG. 4D). Therefore, the production efficiency of the substrate for an organic EL element can be improved, and moreover, the production cost can be cut back.

Furthermore, in the case the organic EL element is produced using a substrate for an organic EL element produced by the present invention, the organic EL layer can easily be formed in a pattern, utilizing the wettability difference of the wettability changeable pattern.

Moreover, as mentioned above, since the barrier layer has the function of preventing the disturbance of the wettability change of the wettability changeable layer, the wettability change process can proceed with a high sensitivity in the wettability changeable pattern forming step so that the thickness of the wettability changeable layer can be made thinner while maintaining the patterning characteristics. Therefore, the charge injection efficiency decline by the wettability changeable layer can be restrained so that an organic EL element having good light emitting characteristics can be produced.

Hereinafter, each step in the production method for the substrate for an organic EL element will be explained.

1. Barrier Layer Forming Step

The barrier layer forming step in the present invention is a step of forming a barrier layer having the charge injecting property or the charge transporting property, and the function of preventing the disturbance of the wettability change of the wettability changeable layer by the action of the photocatalyst onto the substrate with the electrode layer and the insulation layer formed.

The barrier layer can be formed by either of the wet process or dry process.

In the case the barrier layer is formed by a wet process, the barrier layer can be formed by, for example, coating a barrier layer forming coating solution containing a positive hole injecting material or a positive hole transporting material onto the substrate with the electrode layer and the insulation layer formed. At the time, the barrier layer forming coating solution may be prepared by dissolving or dispersing in a solvent the positive hole injecting material or the positive hole transporting material. Since the positive hole injecting material or the positive hole transporting material are described in the column of “A. Substrate for an organic EL element 1. Barrier layer”, an explanation is omitted here.

The solvent used for the barrier layer forming coating solution is not particularly limited as long as it can dissolve or disperse the positive hole injecting material or the positive hole transporting material. Specifically, a chloroform, a methylene chloride, a dichloro ethane, a tetrahydro furan, a toluene, a xylene or the like can be presented.

Moreover, the method of coating the barrier layer forming coating solution is not particularly limited as long as it is a method capable of coating onto the substrate with the electrode layer and the insulation layer formed, but it is preferably a method capable of forming the barrier layer evenly. As such a coating method, for example, a dip coating method, a roll coating method, a blade coating method, a spin coating method, a micro gravure coating method, a gravure coating method, bar coating method, a wire bar coating method, a casting method, an ink jet method, a LB method, a flexo printing method, an offset printing method, a screen printing method or the like can be presented.

On the other hand, in the case of forming the barrier layer by a dry process, the barrier layer can be formed by, for example, the deposition method or the like, using a positive hole injecting material or a positive hole transporting material.

2. Wettability Changeable Layer Forming Step

The wettability changeable layer forming step in the present invention is the step of forming the wettability changeable layer to have the wettability change by the action of the photocatalyst accompanied by the energy irradiation on the barrier layer. The wettability changeable layer can be formed by coating and drying the wettability changeable layer forming coating solution on the barrier layer.

The wettability changeable layer forming coating solution used in the present invention can be prepared optionally by the two embodiments of the wettability changeable layer mentioned in the item of “A. Substrate for an organic EL element 2. Wettability changeable layer.” For example in the case the wettability changeable layer contains a photocatalyst so as to have the wettability change by the action of the photocatalyst accompanied by the energy irradiation as a photocatalyst containing layer (first embodiment), a photocatalyst containing layer forming coating solution containing a photocatalyst and a material to have the wettability change by the action of the photocatalyst is used. Moreover, for example in the case the wettability changeable layer comprises a photocatalyst processing layer containing a photocatalyst and a wettability variable layer to have the wettability change by the action of the photocatalyst accompanied by the energy irradiation (second embodiment), a photocatalyst processing layer forming coating solution containing a photocatalyst and a wettability variable layer forming coating solution containing the material which the wettability thereof changes by the action of the photocatalyst are used for forming each layer.

The wettability changeable layer forming coating solution can be prepared by dissolving or dispersing the photocatalyst, the material to have the wettability change by the action of the photocatalyst and the other additives, using water or a solvent Since the photocatalyst, the material to have the wettability change by the action of the photocatalyst, and other additives are mentioned in the column of “A. Substrate for an organic EL element 2. Wettability changeable layer”, explanation is omitted here.

The solvent used for the wettability changeable layer forming coating solution is not particularly limited as long as it can be mixed with the photocatalyst, the material to have the wettability change by the action of the photocatalyst, or the like, without influencing the patterning characteristics by aggregation, precipitation or another phenomenon. As such a solvent, alcohols such as a methanol, an ethanol, an iropropanol and a butanol, an acetone, an acetonitrile, an ethylene glycol monomethyl ether, an ethylene glycol dimethyl ether, an ethylene glycol monoethyl ether, an ethylene glycol monoethyl ether acetate, a diethyl glycol monomethyl ether, a diethyl glycol monoethyl ether, a diethyl glycol monoethyl ether acetate, a propylene glycol monomethyl ether, a propylene glycol monoethyl ether, a propylene glycol monomethyl ether acetate, a methyl acetate, an ethyl acetate, a butyl acetate, a toluene, a xylene, a methyl lactate, an ethyl lactate, an ethyl pyruvate, a 3-methoxy methyl propionate, a 3-ethoxy ethyl propionate, a dimethyl formamide, a dimethyl sulfoxide, a dioxane, an ethylene glycol, a hexamethyl triamide phosphate, a pyridine, a tetrahydro furan, a N-methyl pyrolidinone or the like can be presented. These solvents may be used as a mixture of two or more kinds.

Moreover, the coating method of the coating solution for forming the wettability changeable layer is not particularly limited as long as it is a method capable of coating the wettability changeable layer forming coating solution onto the barrier layer. For example, a spin coating method, an ink jet method, a casting method, a LB method, a dispenser method, a micro gravure coating method, a gravure coating method, a bar coating method, a roll coating method, a wire bar coating method, a dip coating method, a flexo printing method, an offset printing method, a screen printing method or the like can be presented.

The drying method of the wettability changeable layer forming coating solution is not particularly limited as long as it is a method capable of coating the wettability changeable layer forming an even wettability changeable layer. For example, a method of using a hot plate, an infrared ray heater, or an oven can be presented.

3. Wettability Changeable Pattern Forming Step

The wettability changeable pattern forming step in the present invention is a step of forming a wettability changeable pattern by the energy irradiation in a pattern to the wettability changeable layer so as to change the wettability of the wettability changeable layer.

Although the action mechanism by the photocatalyst in the wettability changeable layer is not always clear, it is considered that the photocatalyst generates the oxidation reduction reaction by the energy irradiation so as to generate the active oxygen species such as the super oxide (O₂—) and a hydroxyl radical (.OH) so that the generated active oxygen species influence the chemical structure of the organic substance.

The energy irradiation (exposure) in the present invention is the concept including the irradiation of any energy line capable of exciting the photocatalyst. In addition to the ultraviolet ray, the visible light beam and the infrared ray, the electromagnetic waves and the radiations of a wavelength shorter or longer than the same are included as well.

The energy irradiation method is not particularly limited as long as it is a method capable of changing the wettability of the wettability changeable layer. Moreover, the energy irradiation may be carried out using a mask such as a photo mask, with a purposed pattern formed. Thereby, the energy irradiation in a purposed pattern can be enabled so that the wettability of the wettability changeable layer can be changed in a pattern. At the time, the kind of the mask to be used is not particularly limited as long as the energy irradiation in a purposed pattern can be enabled. It may be a photo mask or the like with a light shielding part formed in a energy transmittable material, or it may be a shadow mask or the like with a hole part formed in a purposed pattern. As a material for the mask, specifically, an inorganic substance such as a metal, a glass or a ceramic, or an organic substance such as a plastic or the like, can be cited.

Furthermore, in the case a light shielding part is formed on the substrate to be used, the energy irradiation may be the entire surface exposure from the substrate side, utilizing the light shielding part. Thereby, the energy can be directed only to the wettability changeable layer at a position without formation of the light shielding part so as to change the wettability of the wettability changeable layer. In this case, since it is unnecessary to use the mask or to irradiate a laser ray for drawing irradiation, the positioning or expensive device for drawing irradiation are not required. Thus it is advantageous.

For energy irradiation, ultraviolet ray is normally used. Specifically, a wavelength of the ultraviolet ray is set in a range of 400 nm or Less, preferably in a range of 150 nm to 380 nm. This is because, as mentioned above, a preferable photocatalyst used in the wettability changeable layer is the titanium dioxide and it is preferable to use the light of the above wavelength as energy to activate the photocatalyst action with the titanium dioxide.

As for the light source that can be used for such an energy irradiation, various light sources such as a mercury lamp, a metal halide lamp, a xenon lamp, and an excimer lamp can be cited. The energy can be irradiated using a laser such as an excimer or YAG. By using the laser to irradiate the energy, the positioning of the photomask mentioned above or the like becomes unnecessary, thus the wettability of the wettability changeable Layer can be changed highly precisely without forming the light shielding part on the substrate.

Moreover, in the case an anatase type titanium dioxide is used as the photocatalyst, since the excitation wavelength of the anatase type titanium dioxide is 380 nm or less, the energy irradiation can be carried out with an ultraviolet ray. For the light source which radiates such ultraviolet ray, a high pressure mercury lamp (154, 313, 365, 405, 436, 546, 577 nm), a super high pressure mercury lamp (250 to 600nm), a metal halide lamp (250 to 600 nm), a xenon lamp (300 to 1100 nm), an excimer laser, or other ultraviolet ray light sources can be used.

The energy irradiation amount at the time of the energy irradiation is an irradiation amount necessary for changing the wettability of the wettability changeable layer by the action of the photocatalyst in the wettability changeable layer.

The wettability changeable layer used in the present invention has the wettability change by the action of the photocatalyst accompanied by the energy irradiation so that the contact angle with respect to a liquid is changed to the lower direction. By the energy irradiation in a pattern to the wettability changeable layer, a wettability changeable pattern comprising the lyophilic region in the portion with the energy irradiation and the liquid repellent region of the energy unirradiated portion can be formed.

Here, the lyophilic region is a region having a small contact angle with respect to a liquid, and it refers to a region having a good wettability to the organic EL layer forming coating solution used at the time of producing an organic EL element using a substrate for an organic EL element produced by the present invention. Moreover, the liquid repellent region is a region having a large contact angle with respect to a liquid, and it denotes a region having a poor wettability with respect to the organic EL layer forming coating solution.

It is preferable that the contact angles with respect to the organic EL layer forming coating solution in the lyophilic region formed by the energy irradiation and the liquid repellent region without the energy irradiation differ by at least 1′ or more, preferably 5° or more, and particularly preferably 10° or more.

Moreover, about the wettability changeable layer, in the region irradiated with energy, that is, in the lyophilic region, preferably, the contact angle with a liquid having a surface tension of 40 mN/m is 9° or less, more preferably, the contact angle with a liquid having a surface tension of 50 mN/m is 10° or less, and even more preferably the contact angle with a liquid having a surface tension of 60 mN/m is 10° or less for the following reason: in the case the contact angle in the portion with the energy Irradiation, that is, the lyophilic region with respect to a liquid is high, spreading the organic EL layer forming coating solution may be poor in this portion at the time of forming the organic EL layer so that a problem of lacking of the organic EL layer, in particular, the light emitting layer or the like may be generated.

On the other hand, about the wettability changeable layer, in the region not irradiated with energy, that is, in the liquid repellent region, preferably, the contact angle with a liquid having a surface tension of 40 mN/m is 10° or more, more preferably, the contact angle with a liquid having a surface tension of 30 mN/m is 1° C. or more, and even more preferably the contact angle with a liquid having a surface tension of 20 mN/m is 10° or more. Since the portion without the energy irradiation is the portion required to have the liquid repellent, in the case the contact angle with respect to a liquid is small, due to the insufficient liquid repellent, the patterning characteristics may be lowered at the time of forming the organic EL layer.

The contact angle with respect to a liquid here is obtained from the results or a graph of the results of measuring (30 seconds after of dropping liquid droplets from a micro syringe) the contact angle with respect to liquids having various surface tensions using a contact angle measuring device (CA-Z type manufactured by Kyowa Interface Science, Co., Ltd). Moreover, at the time of the measurement, as the liquids having the various surface tensions, wetting index standard solution manufactured by JUNSEI CHEMICAL CO., LTD. were used.

D. Production Method for the Organic EL Element

Next, the production method for the organic EL element of the present invention will be explained.

The production method for an organic EL element of the present invention comprising: a substrate for an organic EL element forming step using the production method for the substrate for an organic EL element mentioned above, an organic EL layer forming step of forming an organic EL layer comprising at least a light emitting layer in a pattern on the wettability changeable layer of the substrate for an organic EL element obtained by the substrate for an organic EL element forming step, and a counter electrode forming step of forming a counter electrode on the organic EL layer.

According to the present invention, since the above-mentioned production method for the substrate for an organic EL element is used, an organic EL element having the excellent patterning characteristics and light emitting characteristics can be produced efficiently by a simple process.

For the substrate for an organic electroluminescent element forming step, since it is the same as the one explained the column of “C. Production method for the substrate for an organic EL element“, explanation is omitted here. Hereinafter, an organic EL layer forming step and a counter electrode forming step of the production method for the organic EL element of the present invention will be explained.

1. Organic EL Layer Forming Step

The organic EL layer forming step in the present invention is a step of forming an organic EL layer having at least a light emitting layer in a pattern on the wettability changeable layer of the substrate for an organic El element obtained in the substrate for an organic El element forming step. The organic EL layer can be formed by coating an organic EL layer forming coating solution on the wettability changeable layer with the wettability changeable pattern formed.

The organic EL layer formed by this step comprises one layer or a plurality of organic layers including at least a light emitting layer. Since the layer configuration is mentioned in the column of “B. Organic El element 1. Organic EL layer”, explanation is omitted here.

The light emitting layer as the essential configuration of the organic EL layer can be formed by coating a light emitting layer forming coating solution containing a pigment based light emitting material, a metal complex based light emitting material, a polymer based light emitting material or the like. Such a light emitting layer forming coating solution can be prepared by dissolving or dispersing the light emitting material and the other additives in a solvent. Since the light emitting material and the other additives are mentioned in the column of “B. Organic EL element 1. Organic EL layer”, explanation is omitted here.

The solvent used for the light emitting layer forming coating solution is not particularly limited as long as it can dissolve or disperse the plight emitting material. Specifically, a chloroform, a methylene chloride, a dichloro ethane, a tetrahydro furan, a toluene, a xylene or the like can be presented.

Moreover, the method of coating the light emitting layer forming coating solution is not particularly limited as long as it is a method capable of coating onto the wettability changeable layer, but it is preferably a method capable of forming the light emitting layer evenly and highly precisely. As such a coating method, for example, a dip coating method, a roll coating method, a blade coating method, a spin coating method, a micro gravure coating method, a gravure coating method, bar coating method, a wire bar coating method, a casting method, an ink jet method, a LB method, a flexo printing method, an offset printing method, a screen printing method or the like can be presented.

Moreover, the positive hole injection and transporting layer, the electron injection and transporting layer or the like as the charge injection and transporting layer can be formed in the same manner as the light emitting layer.

Furthermore, in the case the organic EL layer is formed by laminating two or more organic layers, the organic layers other than the organic layer formed immediately above the wettability changeable layer can also be formed by, for example, a common deposition method without limitation to the forming method by coating.

2. Counter Electrode Layer Forming Step

The counter electrode layer forming step in the present invention is a step of forming a counter electrode layer on the organic EL layer.

As for he method of forming counter electrode layer, a conventional forming method can be employed. For example, PVD method such as vacuum deposition method, sputtering method, or ion plating method, or CVD method can be cited.

The present invention is not limited to the embodiments. The embodiments are merely examples, and any one having the substantially same configuration as the technological idea disclosed in the claims of the present invention and the same effects is included in the technological scope of the present invention.

### EXAMPLES

Hereinafter, the present invention will be explained specifically with reference to the examples and the comparative example.

### Example 1

A transparent electrode layer (ITO film) was formed in a pattern onto a 150 mm square glass substrate, and an insulation layer (TFR-H produced by TOKYO OHKA KOGYO CO., LTD., a positive type photosensitive resin) was formed so as to cover the end part of the ITO film. By coating a cyclohexanone solution of a polyvinyl carbazol on the glass substrate with the transparent electrode layer and the insulation layer formed using a spin coater, a 20 nm film thickness barrier layer was formed. Next, a wettability changeable layer forming coating solution made from an isopropyl alcohol solution of a fluoroalkyl alkoxy silane and a titania sol solution was applied and dried on the barrier layer using a spin coater so as to form a film to have a 70 nm film thickness. Furthermore, by the UV irradiation via a pattern mask for a 6 minutes UV irradiation time, the wettability changeable pattern was formed on the wettability changeable layer so as to produce a substrate for an organic EL element.

### Comparative Example 1

In the same manner as in the example 1 except that the barrier layer was not formed in the example 1, a substrate for an organic EL element was produced.

### Evaluation

The results of the contact angle measurement in the UV irradiated region of the wettability changeable pattern on the wettability changeable layer in the case of using pure water as the measurement solvent for the substrates for an organic EL element of the example 1 and the comparative example 1 are shown in the following table 1.

TABLE 1

| | Initial contact | UV irradiation | Contact angle after |
|---|---|---|---|
| | angle (°) | time (minute) | the UV irradiation (°) |
| Example 1 | 100 | 6 | 5 or less |
| Comparative | 75 | 6 | 50 |
| Example 1 | | | |

Moreover, an ink was applied onto the UV irradiated region of the wettability changeable pattern on the wettability changeable layer of the substrate for an organic EL element. As to the substrate for an organic EL element of the example 1, it was spread well, however, as to the substrate for an organic EL element of the comparative example 1, it was spread poorly.

### Example 2

A light emitting layer was formed using the substrate for an organic EL element of the example 1 by coating and drying a xylene solution of a light emitting material made from a polyvinyl carbazol and a coumarin derivative by a syringe method using a micro syringe in the UV irradiated region of the wettability changeable pattern of the wettability changeable layer. Then, an Ag film was formed on the light emitting layer as the counter electrode layer. Thereby, an organic EL element was produced.

Despite the formation of the wettability changeable layer, the obtained organic EL element has the good light emitting characteristics.

### Example 3

In the same manner as in the example 1 except that the barrier layer was formed as follows, a substrate for an organic EL element was produced.

A film of a copper phthalocyanine was formed on a glass substrate with the transparent electrode layer and the insulation layer formed using the vacuum deposition method so as to form a 40 nm film thickness barrier layer.

According to the same evaluation as the example 1 for the substrate for an organic EL element of the example 3, the same results as the example 1 were obtained.

### Example 4

In the same manner as in the example 1 except that the barrier layer was formed as follows, a substrate for an organic EL element was produced.

A titania sol solution was applied on a glass substrate with the transparent electrode layer and the insulation layer formed using a spin coater so as to form a 60 nm film thickness barrier layer.

According to the same evaluation as the example 1 for the substrate for an organic EL element of the example 4, the same results as the example 1 were obtained.

What is claimed is:

1. A substrate for an organic electroluminescent element comprising a substrate, an electrode layer formed in a pattern on the substrate, an insulation layer formed between the electrode layer on the substrate, a barrier layer formed on the electrode layer and the insulation layer, and a wettability changeable layer formed on the barrier layer to have a wettability change by an action of a photocatalyst accompanied by an energy irradiation,
wherein the barrier layer has a charge injecting property or a charge transporting property, and a function of preventing a disturbance of the wettability change of the wettability changeable layer by the action of the photocatalyst.

2. The substrate for an organic electroluminescent element according to claim 1, wherein the wettability changeable layer contains the photocatalyst so as to have the wettability change by the action of the photocatalyst accompanied by the energy irradiation.

3. The substrate for an organic electroluminescent element according to claim 1, wherein the wettability changeable layer comprises a photocatalyst processing layer containing the photocatalyst and a wettability variable layer to have the wettability change by the action of the photocatalyst accompanied by the energy irradiation.

4. The substrate for an organic electroluminescent element according to claim 1, wherein the wettability changeable layer contains an organopolysiloxane containing a fluoroalkyl group.

5. The substrate for an organic electroluminescent element according to claim 2, wherein the wettability changeable layer contains an organopolysiloxane containing a fluoroalkyl group.

6. The substrate for an organic electroluminescent element according to claim 3, wherein the wettability changeable layer contains an organopolysiloxane containing a fluoroalkyl group.

7. An organic electroluminescent element comprising the substrate for an organic electroluminescent element according to claim 1, an organic electroluminescent layer comprising at least a light emitting layer formed on the wettability changeable layer of the substrate for an organic electroluminescent element, and a counter electrode layer formed on the organic electroluminescent layer.

8. An organic electroluminescent element comprising the substrate for an organic electroluminescent element according to claim 2, an organic electroluminescent layer comprising at least a light emitting layer formed on the wettability changeable layer of the substrate for an organic electroluminescent element, and a counter electrode layer formed on the organic electroluminescent layer.

9. An organic electroluminescent element comprising the substrate for an organic electroluminescent element according to claim 3, an organic electroluminescent layer comprising at least a light emitting layer formed on the wettability changeable layer of the substrate for an organic electroluminescent element, and a counter electrode layer formed on the organic electroluminescent layer.

10. A production method for a substrate for an organic electroluminescent element comprising:
a barrier layer forming step of forming a barrier layer having a charge injecting property or a charge transporting property, and a function of preventing a disturbance of a wettability change of a wettability changeable layer by an action of a photocatalyst on a substrate with an electrode layer and an insulation layer formed;
a wettability changeable layer forming step of forming the wettability changeable layer to have the wettability change by the action of the photocatalyst accompanied by an energy irradiation on the barrier layer; and
a wettability changeable pattern forming step of forming a wettability changeable pattern with a wettability of the wettability changeable layer changed by the energy irradiation in a pattern to the wettability changeable layer.

11. A production method for an organic electroluminescent element comprising:
a substrate for an organic electroluminescent element forming step using the production method for a substrate for an organic electroluminescent element according to claim 10;
an organic electroluminescent layer forming step of forming an organic electroluminescent layer comprising at least a light emitting layer in a pattern on the wettability changeable layer of a substrate for an organic electroluminescent element obtained by the substrate for an organic electroluminescent element forming step; and
a counter electrode forming step of forming a counter electrode on the organic electroluminescent layer.
